(19) United States
(12) Patent Application Publication
(10) Pub. No.: US 2020/0350452 A1
(43) Pub. Date: Nov. 5, 2020

(54) HOLOGRAPHIC SYSTEM FOR EXTENDED ENERGY CAPTURE

(71) Applicant: Arizona Board of Regents on Behalf of the University of Arizona, Tucson, AZ (US)

(72) Inventor: Raymond K. Kostuk, Tucson, AZ (US)

(21) Appl. No.: 16/481,404

(22) PCT Filed: Jan. 25, 2018
(86) PCT No.: PCT/US18/15311

§ 371 Date: Jul. 26, 2019

Related U.S. Application Data
(60) Provisional application No. 62/451,413, filed on Jan. 27, 2017.

(51) Int. Cl. H01L 31/054

(52) U.S. Cl. CPC H01L 31/054; H01L 31/0684

(57) ABSTRACT

The present disclosure describes a solar system comprising a bi-facial photo-voltaic module comprising one or more solar cells disposed adjacent a transparent encapsulant, the bifacial photo-voltaic module disposed in a substantially vertical configuration relative to a horizon and a holographic optical element disposed adjacent an end of the bi-facial photo-voltaic module, the holographic optical element configured to direct incident light toward one or more surfaces of the bi-facial photo-voltaic module.

### GOVERNMENT RIGHTS

This invention was made with government support under Grant Nos. EEC1041895 and ECCS1405619 awarded by the National Science Foundation (NSF). The government has certain rights in the invention.

### TECHNICAL FIELD

The technical field generally relates to energy capture. More specifically, the technical field relates to solar systems configured with holographic systems for extended energy capture.

### BACKGROUND

Efficient collection and concentration of radiant energy is useful in a number of applications and is of particular value for devices that convert solar energy to electrical, thermal or biofuel energy. As an example, bifacial photovoltaic (PV) solar cells may be designed to capture and convert sunlight on the front and back surfaces of the cell. Such a configuration allows for new mounting and application areas not available with mono-facial cells. As a further example, vertically mounted bi-facial PV solar cells may be implemented to maximize solar energy conversion during morning and late afternoon periods, as shown in FIG. 1. The vertically mounted bi-facial PV solar cells may offset the higher energy demands that may occur during those time periods. However, vertically mounted bi-facial PV solar cells may be limited in capturing direct sunlight during midday time periods, as shown in FIG. 1.

### SUMMARY

Described herein are solar systems configured with holographic systems for extended energy capture. The systems of the present disclosure may address one or more problems in the art by using a holographic optical element that captures direct sunlight during midday time periods (e.g., 10 am-2 pm) and diffracts light to the surface of the vertical mounted PV panel. The systems of the present disclosure may be configured (e.g., optimized) for various time periods and may be based on the power generation plot of the vertically mounted solar cell. In certain aspects, the grating structure of the holographic optical element (e.g., collector, concentrator, etc.) may be configured to optimize collection of the most effective portion of the solar illumination spectrum for energy conversion by the vertical mounted PV module. In certain aspects, the diffraction angle and/or the spectral range diffracted by the hologram may be controlled to optimize collection efficiency during midday time periods.

The area of the holographic optical element may be configured to set a limit on the amount of direct solar illumination that can be captured during midday time periods. The holographic optical element may be disposed (e.g., mounted directly) on top of a vertically mounted PV module or displaced in a horizontal direction away from the module.

In an example embodiment, a solar system comprises a bi-facial photo-voltaic module comprising one or more solar cells disposed adjacent a transparent encapsulant, the bi-facial photo-voltaic module disposed in a substantially vertical configuration relative to a horizon, and a holographic optical element disposed adjacent an end of the bi-facial photo-voltaic module, the holographic optical element configured to direct incident light toward one or more surfaces of the bi-facial photo-voltaic module.

In an example embodiment, a solar system comprises a photo-voltaic module comprising one or more solar cells disposed adjacent a transparent encapsulant, the bi-facial photo-voltaic module disposed in a substantially vertical configuration relative to a horizon and a holographic optical element disposed adjacent an end of the photo-voltaic module, the holographic optical element configured to direct incident light toward one or more surfaces of the photo-voltaic module.

### BRIEF DESCRIPTION OF THE DRAWINGS

FIG. 1 illustrates plots of yearly average of daily power distribution for mono-facial and bi-facial PV panel configurations according to the prior art.

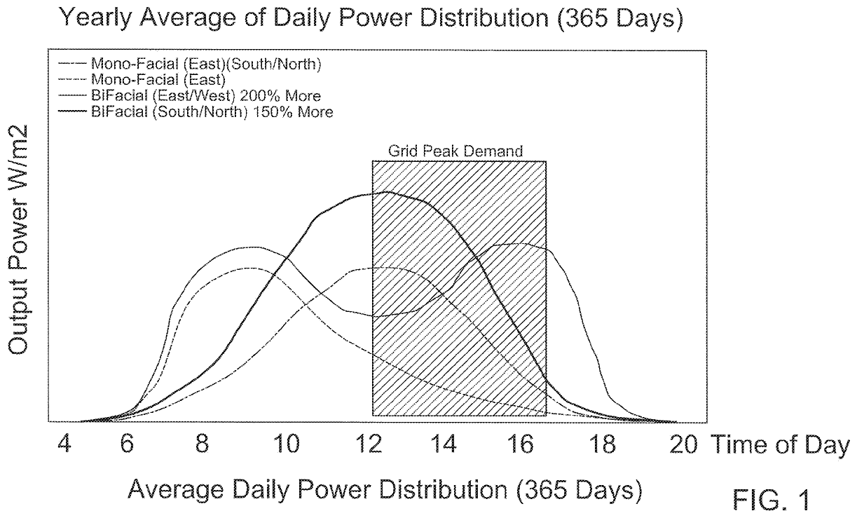

FIG. 2 is a schematic representation of a solar system according to aspects of the present disclosure.

FIGS. 3A-3B illustrate Bragg diagrams for constructing and reconstructing a hologram.

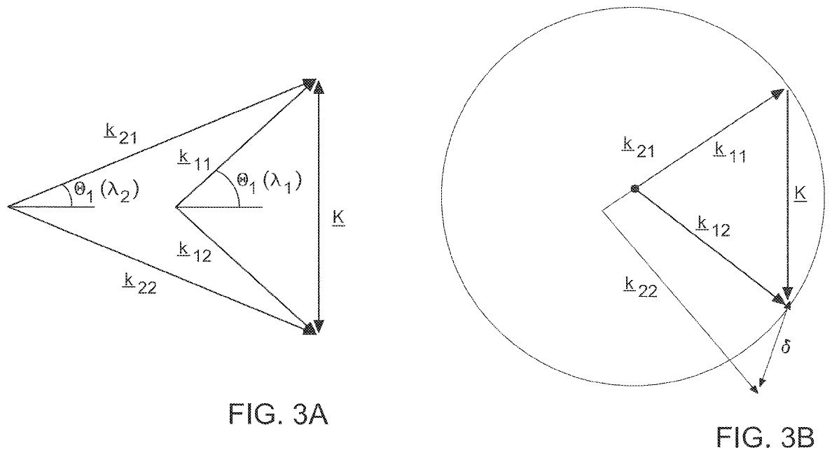

FIG. 4 illustrates a plot of the E_{AM1.5} spectrum (orange 400), spectral response (SR) of silicon (blue 402), and the product of E_{AM1.5}(λ)·SR(λ) (magenta 404) as a function of wavelength.

### DETAILED DESCRIPTION

The systems of the present disclosure may comprise a holographic optical element, such as a holographic collector or concentrator, that may be configured to capture direct sunlight during midday time periods and to diffract light to a surface of a vertically mounted PV panel. Direct light may comprise non-reflected light, non-scattered light, solar light on a clear, non-cloudy day, etc.) In certain aspects, the grating structure of the holographic optical element (e.g., collector, concentrator, etc.) may be configured to optimize collection of the most effective portion of the solar illumination spectrum for energy conversion by the vertical mounted PV module. In certain aspects, the diffraction angle and/or the spectral range diffracted by the hologram may be controlled to optimize collection efficiency during midday time periods.

Factors that may be considered in the design/configuration of the holographic optical element may comprise: 1) the diffracted ray angles as a function of the position and spectrum of the solar illumination; and 2) the diffraction efficiency of the hologram as a function of the position and spectrum of the sun.

As an example, the diffraction angle may be determined by the grating equation:

$$sin {θ}_{d} - sin {θ}_{inc} = \frac{λ}{{Λ}_{T}} ,$$

where θ_{d} is the angle of diffraction as measured from a normal direction to the hologram surface, θ_{inc} is the angle of incidence of sunlight also measured from a normal to the grating surface, Λ_{T} is the grating period along the grating surface, λ is the wavelength of the incident sunlight.

The diffraction efficiency of the hologram may be determined by coupled wave analysis. As an example, for a transmission hologram with fringes oriented perpendicular to the hologram surface, the diffraction efficiency may be approximated as:

$$η = {sin}^{2} ( \frac{πΔ nd}{{λ}_{B} cos {θ}_{inc}} )$$

where Δn is the refractive index modulation of the hologram, d is the thickness of the hologram, and λ_{B} is the Bragg wavelength of the hologram. θ_{inc} in this case would also be the Bragg angle for the hologram. The Bragg wavelength and angle may be considered as the conditions for maximum diffraction efficiency of the hologram and can be expressed in the vector Bragg equation:

k₁−k₂=K,

where k₁ and k₂ are the propagation vectors (with magnitude of 2πn/λ) and K is the grating vector that is perpendicular to the grating planes and has magnitude 2π/Λ where Λ is the volume grating period.

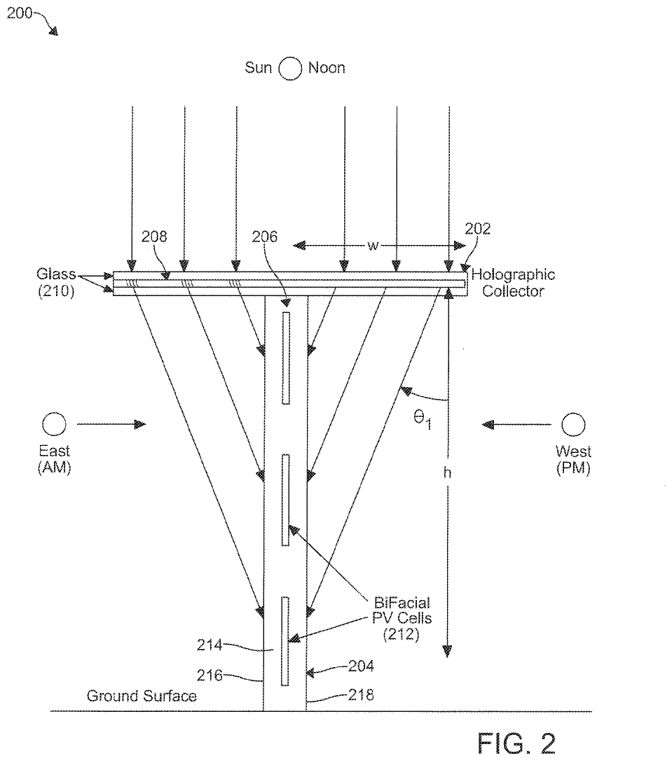

As an illustrative example, if the wavelength and angle are both changed the diffraction efficiency can remain high (such as illustrated in the configuration shown in FIG. 2). As an example, high diffraction efficiency may be 60% or above. However, if either the wavelength or angle is fixed the diffraction efficiency will decrease. This is illustrated by the length of the vector δ in the diagram in FIG. 2 on the right.

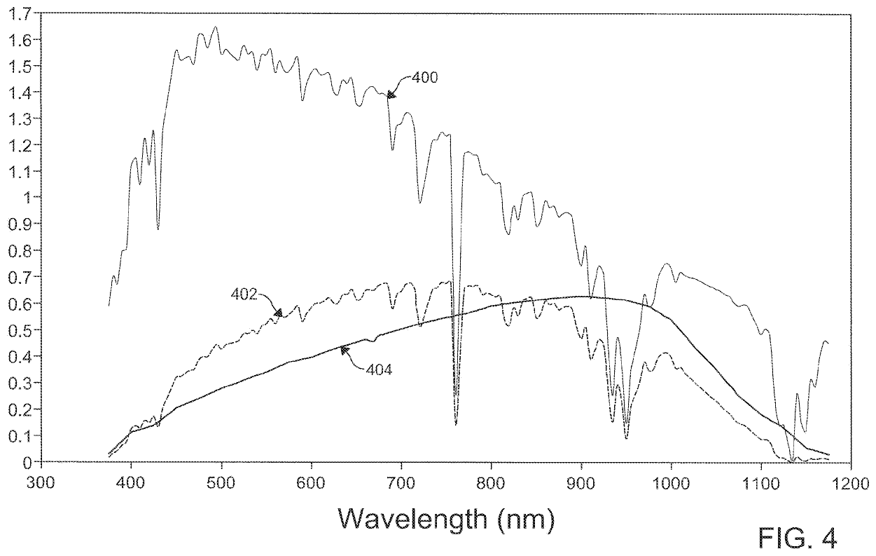

The peak diffraction efficiency wavelength may be determined by evaluating the properties of the incident illumination (assume the Air Mass 1.5 solar spectrum E_{AM1.5}) and the spectral responsivity (SR) of the PV cell. As an example, FIG. 4 shows plots for the E_{AM1.5} spectrum and the spectral responsivity of silicon as a function of wavelength. Also shown is the product of these two spectra E_{AM1.5}(λ)·SR(λ). From FIG. 4, it can be seen that capturing the power available from 500-750 nm or from 770-925 nm will result in the highest output from the PV cell and the most power conversion. Therefore, setting the peak diffraction efficiency wavelength of the hologram in one of these spectral regions (or both) may provide the most benefit. Other configurations and optimization calculations may be used.

### Holographic Optical Element Design Procedure

Based on one or more of the above properties, a hologram may be designed/configured by: 1) selecting the area of the holographic optical element to provide the desired improvement to the midday drop in power output of the vertical mounted bifacial PV module; 2) computing the diffraction angle with a normally incident plane wave; 3) determine the peak diffraction efficiency wavelength; and 4) use the angle and wavelength parameters to set the exposure conditions for fabricating the hologram. The above procedure is presented as a non-limiting example only. Other procedures and configurations are contemplated herein.

As described herein, vertically mounted bi-facial PV are capable of increased solar energy capture during morning and late afternoon periods. This offsets the higher energy demands during those time periods. The problem with deploying PV modules in this manner is that they cannot capture direct sunlight during midday time periods.

FIG. 2 illustrates an exemplary solar system 200 comprising a holographic optical element 202 and a PV module 204. The holographic optical element 202 may be configured as a separate component from the PV module 204 that may be optimized for different types of PV modules/cells. The holographic optical element 202 may be configured to be coupled to the PV module 204 such as by fastening (e.g., bolting) the holographic optical element 202 to a top (vertically) portion 206 of the PV module 204. As such, the holographic optical element 202 may be configured to be coupled to existing PV modules with little to no modification of the PV module. Alternatively, the holographic optical element 202 may be integrated with the PV module 204 as a generally uniform component system. Although the solar system 200 is shown comprising the holographic optical element 202 and the PV module 204, any number of components including PV modules, solar cells (mono-facial and/or bi-facial), holographic optical elements, solar collectors, solar concentrators, spacers, and the like.

The holographic optical element 202 may be or comprise a holographic collector, a holographic concentrator, or the like. The holographic optical element 202 may comprise and optical grating 208 disposed adjacent one or more layers 210 such as a substrates, encapsulants, and/or transparent mediums. As shown in FIG. 2, the holographic optical element 202 comprises an optical grating layer 208 interposed between a pair of glass payers 210. As an illustrative example, the holographic optical element 202 may be configured to receive incident, direct radiant energy (e.g., solar energy, solar light, etc.). The holographic optical element 202 may be configured to receive direct radiant energy from the sun during a predetermined time period such as between 10 am and 2 pm. The holographic optical element 202 may be configured to receive direct radiant energy during other time periods.

The PV module 204 may be or comprise a mono-facial and/or a bi-facial PV module. As shown, the PV module 204 comprises a bi-facial photo-voltaic module having one or more PV solar cells 212 (e.g., bi-facial) interposed in an encapsulants 214 or between a pair of transparent encapsulants. As an example, the encapsulants 214 may comprise glass or other transparent material. The PV module 204 may be disposed in a substantially vertical configuration relative to a horizon such as the ground. As shown, the PV module 204 may be positioned such that a pair of opposing surfaces 216, 218 generally face east and west, respectively. Other configurations and positions may be used.

The holographic optical element 202 may be disposed adjacent an end such as top portion 206 of PV module 204 and may be configured to direct (e.g., diffract) light toward the surfaces 216, 218 of the PV module 204. As an example, solar illumination may be assumed to be incident in a direction normal to the hologram surface of holographic optical element 202 θ_{inc}=0°. The diffraction angle may be determined from:

θ_{d}=arctan(w/h),

where w is the width of the holographic optical element 202 as determined from the area required for the holographic optical element 202, and h is the height of the bifacial PV module 204 as shown in FIG. 2. The design wavelength may be selected front consideration of the PV module 204 spectral responsivity and the incident solar illumination spectrum as shown in FIG. 4. For the situation shown in FIG. 4, 600 nm is a wavelength that is in the center of the broadest part of the useable spectrum and is a good design choice. The lateral and volumetric grating periods are then determined using the grating equation and the Bragg condition described above.

The holographic optical element 202 may be formed in a material such as dichromated gelatin or a photopolymer that has a thickness (d) and refractive index modulation Δn to give high diffraction efficiency and the quality factor:

$$Q = \frac{2 π d λ}{n {Λ}^{2}}$$

which may be evaluated to ensure that the hologram is operating in a range where high diffraction efficiency occurs. This may require that Q>10 for the material and hologram parameters. As the angle of the sun changes about the noon position (i.e. normal incidence) the diffraction efficiency and diffracted peak wavelength will vary about the design values and will affect the response of the PV cell. Therefore, the diffraction efficiency and its effect on the power and energy output of the PV cells are then evaluated using coupled wave analysis to determine changes to the design wavelength and angles to decrease the reduction in power near midday. Light will also be reflected from the surface of the glass covering the bifacial PV modules dues to Fresnel reflection losses. These reflections are typically reduced with anti-reflection coatings are also included in the energy yield analysis. Residual reflected light is backscattered from the ground surface and will be partially captured by the PV module surface. After several iterations of varying the design angles and wavelength, the holographic material is exposed and processed and then sealed between pieces of glass or durable plastic in a manner similar to sealing the bifacial PV modules.

The present disclosure comprises at least the following aspects:

Aspect 1: A solar system comprising: a holographic optical element configured to be disposed adjacent an end of a vertically-mounted photo-voltaic module, the holographic optical element further configured to direct incident light toward one or more surfaces of the bi-facial photo-voltaic module.

Aspect 2: The solar system of aspect 1, wherein photo-voltaic module comprises a bi-facial photo-voltaic module having one or more solar cells disposed adjacent a transparent encapsulant.

Aspect 3: The solar system of aspect 2, wherein the transparent encapsulant encloses the one or more solar cells.

Aspect 4: The solar system of aspect 2, wherein the transparent encapsulant comprises a pair of encapsulant layers and the one or more solar cells are interposed between the pair of encapsulant layers.

Aspect 5: The solar system of any one of aspects 1-4, wherein the holographic optical element comprises an optical grating.

Aspect 6: The solar system of any one of aspects 1-5, wherein at least a portion of the holographic optical element is orthogonal to the one or more surfaces of the photo-voltaic module.

Aspect 7: The solar system of any one of aspects 1-6, wherein the holographic optical element is configured to diffract incident light toward the one or more surfaces of the photo-voltaic module.

Aspect 8: The solar system of any one of aspects 1-7, wherein holographic optical element is formed from dichromated gelatin or a photopolymer.

Aspect 9: The solar system of any one of aspects 1-8, wherein holographic optical element has a thickness (d) and refractive index modulation Δn to give high diffraction efficiency and the quality factor Q>10 as determined by:

$$Q = \frac{2 π d λ}{n {Λ}^{2}} .$$

Aspect 10: A solar system comprising: a photo-voltaic module comprising one or more solar cells disposed adjacent a transparent encapsulant, the bi-facial photo-voltaic module disposed in a substantially vertical configuration relative to a horizon; and a holographic optical element disposed adjacent an end of the photo-voltaic module, the holographic optical element configured to direct incident light toward one or more surfaces of the photo-voltaic module.

Aspect 11: The solar system of aspect 10, wherein the one or more solar cells comprise one or more of a bi-facial solar cell and a mono-facial solar cell.

Aspect 12: The solar system of any one of aspects 10-11, wherein the transparent encapsulant encloses the one or more solar cells.

Aspect 13: The solar system of any one of aspects 10-12, wherein the transparent encapsulant comprises a pair of encapsulant layers and the one or more solar cells are interposed between the pair of encapsulant layers.

Aspect 14: The solar system of any one of aspects 10-13, wherein the holographic optical element comprises an optical grating.

Aspect 15: The solar system of any one of aspects 10-14, wherein at least a portion of the holographic optical element is orthogonal to the one or more surfaces of the photo-voltaic module.

Aspect 16: The solar system of any one of aspects 10-15, wherein the holographic optical element is configured to diffract incident light toward the one or more surfaces of the photo-voltaic module.

Aspect 17: The solar system of any one of aspects 10-16, wherein holographic optical element is formed from dichromated gelatin or a photopolymer.

Aspect 18: The solar system of any one of aspects 10-17, wherein holographic optical element has a thickness (d) and refractive index modulation Δn to give high diffraction efficiency and the quality factor Q>10 as determined by:

$$Q = \frac{2 π d λ}{n {Λ}^{2}} .$$

Aspect 19: The solar system of any one of aspects 10-18, wherein the holographic optical element is integrated with the photo-voltaic module.

Aspect 20: The solar system of any one of aspects 10-19, wherein the holographic optical element is formed separately from the photo-voltaic module and coupled thereto.

As described herein, the holographic collector can extend the energy collection and power collection of vertically mounted bifacial PV modules during midday time periods when output normally drops. The hologram is designed to optimize the diffracted spectrum and angles for optimum output of the bi-facial PV modules.

1. A solar system comprising:
a holographic optical element configured to be disposed adjacent an end of a vertically-mounted photo-voltaic module, the holographic optical element further configured to direct incident light toward one or more surfaces of the bi facial photo-voltaic module.

2. The solar system of claim 1, wherein photo-voltaic module comprises a bi-facial photo-voltaic module having one or more solar cells disposed adjacent a transparent encapsulant.

3. The solar system of claim 2, wherein the transparent encapsulant encloses the one or more solar cells.

4. The solar system of claim 2, wherein the transparent encapsulant comprises a pair of encapsulant layers and the one or more solar cells are interposed between the pair of encapsulant layers.

5. The solar system of claim 1, wherein the holographic optical element comprises an optical grating.

6. The solar system of claim 1, wherein at least a portion of the holographic optical element is orthogonal to the one or more surfaces of the photo-voltaic module.

7. The solar system of claim 1, wherein the holographic optical element is configured to diffract incident light toward the one or more surfaces of the photo-voltaic module.

8. The solar system of claim 1, wherein holographic optical element is formed from dichromated gelatin or a photopolymer.

9. The solar system of claim 1, wherein holographic optical element has a thickness (d) and refractive index modulation Δn to give high diffraction efficiency and the quality factor Q>10 as determined by:
$$Q = \frac{2 π d λ}{n {Λ}^{2}} .$$

10. A solar system comprising:
a photo-voltaic module comprising one or more solar cells disposed adjacent a transparent encapsulant, the bi-facial photo-voltaic module disposed in a substantially vertical configuration relative to a horizon; and
a holographic optical element disposed adjacent an end of the photo-voltaic module, the holographic optical element configured to direct incident light toward one or more surfaces of the photo-voltaic module.

11. The solar system of claim 10, wherein the one or more solar cells comprise one or more of a bi-facial solar cell and a mono-facial solar cell.

12. The solar system of claim 10, wherein the transparent encapsulant encloses the one or more solar cells.

13. The solar system of claim 10, wherein the transparent encapsulant comprises a pair of encapsulant layers and the one or more solar cells are interposed between the pair of encapsulant layers.

14. The solar system of claim 10, wherein the holographic optical element comprises an optical grating.

15. The solar system of claim 10, wherein at least a portion of the holographic optical element is orthogonal to the one or more surfaces of the photo-voltaic module.

16. The solar system of claim 10, wherein the holographic optical element is configured to diffract incident light toward the one or more surfaces of the photo-voltaic module.

17. The solar system of claim 10, wherein holographic optical element is formed from dichromated gelatin or a photopolymer.

18. The solar system of claim 10, wherein holographic optical element has a thickness (d) and refractive index modulation Δn to give high diffraction efficiency and the quality factor Q>10 as determined by:
$$Q = \frac{2 π d λ}{n {Λ}^{2}} .$$

19. The solar system of claim 10, wherein the holographic optical element is integrated with the photo-voltaic module.

20. The solar system of claim 10, wherein the holographic optical element is formed separately from the photo-voltaic module and coupled thereto.
